(19) United States
(12) Patent Application Publication
(10) Pub. No.: US 2013/0029497 A1
(43) Pub. Date: Jan. 31, 2013

(54) Method of Crystallizing Amorphous Silicon Films by Microwave Irradiation

(71) Applicants: Tsung-Shune Chin, Baoshan Township (TW); Tsun-Hsu Chang, Hsinchu (TW); Shih-Chieh Fong, Hsinchu (TW); Hsien-Wen Chao, Hsinchu (TW)

(72) Inventors: Tsung-Shune Chin, Baoshan Township (TW); Tsun-Hsu Chang, Hsinchu (TW); Shih-Chieh Fong, Hsinchu (TW); Hsien-Wen Chao, Hsinchu (TW)

(73) Assignee: NATIONAL TSING HUA UNIVERSITY, Hsinchu (TW)

(21) Appl. No.: 13/399,575

(22) Filed: Feb. 17, 2012

(30) Foreign Application Priority Data
Jul. 29, 2011 (TW) 100126890

(51) Int. Cl. H01L 21/322

(52) U.S. Cl. 438/758; 257/E21.318

(57) ABSTRACT

A method is developed to crystallize amorphous silicon (a-Si) thin films, in cold environment, by combining microwave-absorbing materials (MAM) and microwave irradiation. The MAM is set on top or around of the a-Si thin film. MAM composes of dielectric, magnetic, semiconductor, ferroelectric and carbonaceous material oxides, carbides, nitrides and borides, which will absorb and concentrate electric or magnetic field of the microwave. The microwave frequency is selected from 1 to 50 GHz, at a power density not less than 5 W/cm². Temperature rise of the MAM is monitored and controlled by an optical pyrometer to be less than 600° C., and better be within 400-500° C. The application of MAM at patterned local areas leads to localized heating and crystallization of a-Si film right at the patterns to facilitate manufacture of semiconductor devices.

### CROSS-REFERENCE TO RELATED APPLICATION

This application claims the benefit of priority to Taiwan Patent Application No. 100126890, filed on Jul. 29, 2011, in the Taiwan Intellectual Property Office, the disclosure of which is incorporated herein in its entirety by reference.

### BACKGROUND OF THE INVENTION

1. Field of the Invention

The present invention relates to a method of crystallizing an amorphous silicon thin film of an optoelectronic semiconductor by microwave irradiation, and more particularly to the method of combining a microwave-absorbing material placed on the amorphous silicon thin film and a microwave irradiation with appropriate frequency and power to crystallize amorphous silicon. The present invention uses a microwave-absorbing material to attract and cluster microwave beams to generate heat, such that the amorphous silicon thin film can be heated to a critical temperature, and the clustered microwave beams at this temperature can induce vibrations of a group of atoms of the amorphous silicon, so as to achieve the crystallization at a low temperature and in a short time.

2. Description of the Related Art

Regular thermal annealing is generally used as a conventional way of converting amorphous silicon structures into nanocrystal-microcrystal silicon structures, which is called solid-phase crystallization (SPC). In a conventional heating furnace, a non-crystalline thin film is heated to a temperature above the crystallization temperature, and the crystallization temperature of silicon is generally above 700° C. After a long time of thermal treatment, the original non-crystalline silicon is changed to a crystalline state. The time of the thermal treatment usually takes more than 10 hours. Crystallization occurs, so that heat energy provides sufficient energy to the silicon atoms to overcome the energy barrier for rearranging the atoms, so that the atoms can be rearranged into a more stable crystalline structure. In addition to the heat energy, the crystallization process requires sufficient time before the silicon atoms can be rearranged. The higher the temperature, the shorter is the crystallization time. Therefore, high temperature and long-time thermal treatments are inevitable in solid-phase crystallization, and the required power consumption and manufacturing time are unable to meet the quick production requirements of the industry.

To lower the crystallization temperature, scientists developed a coating film made of a certain metal element for the crystallization of the original amorphous silicon thin film, and this method is called metal-induced crystallization (MIC). There are two kinds of metals used in the method; one kind of metals will not form a silicide such as silver, gold, aluminum and antimony, wherein the atoms of these metals will affect the covalent bond energy of the original silicon to produce a lower transient steady state of the crystallization temperature; and the other kind of metals includes titanium, nickel and copper, which will produce a metal silicide used as a heterogeneous nuclear silicon crystallization. After the metal silicide is diffused and moved, a stable crystalline structure is achieved. In the study of MIC, the lowest crystallization temperature reported is 165° C. when aluminum is used and 380° C. when nickel is used. The crystallization process takes approximately one hour, and the MIC is criticized most for its drawback that the metal used will inevitably contaminate the crystalline silicon.

In an excimer-laser annealing (ELA) method, a focused excimer laser is used for a micro-irradiation to achieve the crystallization quickly, and this method has become an important technology for manufacturing high-performance polysilicon thin film transistors. Pulsed laser is used to heat, re-melt, and re-crystallize semiconductors. In the process, only some of the areas are heated, and the whole is still remains at a low-temperature environment. The low-temperature process allows the ELA method to be applied for glass substrates and even plastic substrates. This is one of the main advantages of the ELA technology, and the other advantages include a good crystallinity and a low defective rate of the polysilicon obtained from the crystallization process. However, the ELA technology can only crystalline a workpiece with an area in the scale of microns for each time of irradiation, but its energy source and time efficiency are insufficient for a large area (in the scale of square meters). What is more, high-end equipments and very high manufacturing costs are required.

In summation, the industry urgently needs effective, quick, low-temperature ways of crystallizing amorphous silicon thin films and capable of processing large-area workpieces, avoiding possible pollutions, saving energy, and minimizing the manufacturing time.

The wave band of the microwave falls within a range from 0.3 GHz to 300 GHz. In present industries, it is common to use microwave to process materials. The use of microwave for processing materials generally places a microwave absorbing material in a microwave field at a low temperature (below 200° C.), so that molecules of the materials will absorb microwave energy directly to produce vibrations or rotations to achieve the heating effect and increasing the reaction efficiency. Common examples include heating, boiling and evaporating water by a microwave oven for defrosting, cooking or drying food, so that microwave ovens are used extensively and become a necessary tool in our daily life due to their high-speed and convenient heat-up without heating the container. Further, a common industrial use of microwave is for processing polymer materials as disclosed by [A. Bhaskar, T. H. Chang, H. Y. Chang, S. Y. Cheng, Thin Solid Films, 515 2891-2896 (2007)].

However, the microwave heating has been applied to sintering non-microwave absorbing high-temperature ceramics, and the heat-generating element capable of absorbing microwave is used for making a container, and the ceramic body in a heating container is sintered at a high temperature produced by the microwave irradiation as disclosed by [R. Roy, D. Agrawal, J. Cheng and S. Gedevanishvili, Nature, 399, 668-670 (1999); K. Saitou, Scripta Materialia, 54, 875-879 (2006); H. Y. Chang, S. Y. Cheng and C. I. Sheu, Materials Letters, 62, 3620-3622 (2008).]

Using microwave irradiation to crystallize amorphous silicon thin films has been disclosed in U.S. Pat. No. 6,528,361 by [J. W. Park, D. G. Moon, B. T. Ahn, H. B. Im, K. R. Lee, Thin Solid Films, 245, 228 (1994); R. Rao, Z. Y. XU, and X. B. Zeng, Journal of Wuhan University of Technology, 17, 25 (2002).] However, this prior art combines the conventional heating furnace with microwave irradiation, and thus the product is huge in size and heavy, wherein a workpiece is heated by the conventional heating furnace to a high temperature first, and then the high-temperature workpiece is transferred into the microwave irradiation furnace and irradiated by microwave, or an opening for guiding the microwave is formed in the heating furnace, such that the workpiece can be heated in a traditional way while being irradiated by the microwave. This technique is applied on crystallizing the amorphous silicon thin film. In the literature, results show that when the temperature is 500° C., the required crystallization time is 9 hours and 20 minutes. If the temperature is 550° C., the required crystallization time is 46 minutes [refer to J. H. Ahn, J. N. Lee, Y. C. Kim, and B. T. Ahn, Current Applied Physics, 2, 135-139 (2002).] Although the aforementioned prior arts also adopt microwave irradiations, they still use the conventional heating furnace, so that the crystallization time is still relatively long, and the applicability of these prior arts on large-area processing is still unknown. In addition, U.S. Pat. No. 6,133,076 has disclosed the method of integrating MIC with the microwave irradiation for crystallizing amorphous silicon.

The aforementioned microwave processing methods still require improvements on the large-area amorphous silicon thin film and their processing time and energy efficiency. Therefore, the present invention provides a novel crystallization method by using microwave irradiations to achieve the crystallization with the effect of a high crystallization percentage (80%) at a low temperature (below 500° C.) within a short time (less than 1800 seconds), without using the conventional heating furnace to save energy significantly.

### SUMMARY OF THE INVENTION

In view of the aforementioned problems of the prior art, it is a primary objective of the invention to provide a method of crystallizing amorphous silicon thin films by microwave irradiation to overcome the problems of the prior art.

To achieve the foregoing objective, the present invention provides a method of crystallizing amorphous silicon thin films by microwave irradiation that combines a microwave-absorbing material with an amorphous silicon thin film, and uses microwave irradiation to crystallize the amorphous silicon thin film. The method comprises the steps of: putting the microwave-absorbing material on top or around of the amorphous silicon thin film to form a composite; and moving the composite into a microwave irradiation chamber, and irradiating the composite by microwave with appropriate frequency and power to crystallize the amorphous silicon thin film.

Preferably, the microwave-absorbing material is metal oxide, magnetic oxide, carbonaceous material, carbide, nitride, silicide, boride, ferroelectric oxide, metal powder, or a combination of the above with semiconducting properties.

Preferably, the microwave-absorbing material is in a form of thin film, micro-particle or lump.

Preferably, the microwave-absorbing material is put on top of or around the amorphous silicon thin film by using thin film plating method, brushing method, spin-coating method, screen printing method, ink jet printing method, heap spray method, substrate insertion method or a combination of the above.

Preferably, the appropriate frequency falls within a range of 1-50 GHz; and the power has a density over 5 watts per square centimeter.

Preferably, a specific pattern is formed at a part of the microwave-absorbing material, and when the microwave irradiation is performed, the amorphous silicon thin film is partially crystallized to form a crystalline silicon film corresponding to the specific pattern.

Preferably, the microwave irradiation chamber is provided for irradiating microwave onto a multi-layer film containing the amorphous silicon of the amorphous silicon thin film, so that the multi-layer film can be removed and transferred to a substrate after the multi-layer film is crystallized.

Therefore, the method of crystallizing amorphous silicon thin films by microwave irradiation in accordance with the present invention can achieve the crystallization with the effect of a high crystallization percentage (80%) at a low temperature (below 500° C.) within a short time (less than 1800 seconds), and without using the conventional heating furnace to save energy significantly.

### BRIEF DESCRIPTION OF THE DRAWINGS

The patent or application filed contains at least one drawing executed in color. Copies of this patent or patent application publication with color drawing(s) will be provided by the Office upon request and payment of the necessary fee.

FIG. 1 shows a simulation view of an electromagnetic field distributed in a microwave field of an elliptic microwave system;

FIG. 2 shows a simulation view of an electromagnetic field distributed in a microwave field of a sample and a simulation view of an electromagnetic field distributed in a microwave field around a microwave-absorbing material; 2(a) shows the distribution view of a microwave field between amorphous silicon thin film and lump and two silicon carbide rods made of a microwave accessory absorbing material; and 2(b) shows the distribution view of a microwave field between an amorphous silicon thin film and silicon carbide particles of a single-layer microwave accessory absorbing material.

FIG. 3 is a TEM photo of a silicon thin film crystallized by microwave heating; 3(a) is a cross-sectional view of a polysilicon thin film; and 3(b) is a cross-sectional view of crystal particles in a silicon thin film.

FIG. 4 shows a Raman spectrum of irradiation process with a microwave power density of 40 watts per square centimeter;

FIG. 5 is a photo of a thin film crystallization region (in grayish black color) and an amorphous region (in grayish white color) taken by an optical microscope;

FIG. 6 is a photo showing the appearance of a crystalline amorphous silicon thin film (Left) and a microwave crystalline amorphous silicon thin film (Right);

FIG. 7 shows photos comparing silicon templates before/after the microwave crystallization process taking place; 7(a) is a photo showing an amorphous silicon thin film before being irradiated by microwave; 7(b) is a photo showing an a crystalline silicon thin film after being irradiated by microwave and crystallized; 7(c) is an optical microscopic photo showing a pattern of an amorphous silicon before being irradiated by microwave; and 7(d) is an optical microscopic photo showing a pattern of an amorphous silicon before being irradiated by microwave and crystallized; and

FIG. 8 is a SEM photo showing a side view of a silicon pattern transferred onto a carbon conductive adhesive tape.

### DETAILED DESCRIPTION OF THE PREFERRED EMBODIMENTS

In the method of crystallizing an amorphous silicon thin film of an optoelectronic semiconductor by microwave irradiation in accordance with the present invention, the amorphous silicon thin film used in a glass, ceramic or silicon chip is put on micro particles, thin films or lumps coated with a layer of microwave-absorbing material, and then the particles, thin films, or lumps are crystallized by microwave irradiation, and this novel method is particularly useful for coating a large-area amorphous silicon thin film.

The step of putting a layer of microwave-absorbing materials on the amorphous silicon thin film refers to putting a material in the microwave field to absorb microwaves to expedite heating up the material. The material can be in a form of particles (micro-particles or nanoparticles) or lumps. The microwave accessory absorbing material designed for the present invention is a material with a high dielectric loss (tan δ=ε″/ε′). According to the principle of heating by microwave, P=2πfε″E2, wherein P is the microwave power absorbed per unit volume; f is the microwave frequency; ε″ is the dielectric loss; E is the intensity of electric field in the material. The microwave-absorbing material is also a material with a conductive loss (including Eddy current).

These microwave-absorbing materials include but not limited to any of the following materials or one of their composites:

A metal oxide with properties of a semiconductor includes chromium oxide, defective manganese oxide (MnOₓ, x=1-2), zinc oxide (ZnO), nickel oxide (NiO), titanium dioxide (TiO₂), hafnium dioxide (HfO₂), tin dioxide (SnO₂), and vanadium dioxide (VO₂), etc.

A magnetic oxide including ferrite and iron oxide (Fe₃O₄), etc.

A carbide including silicon carbide (SiC), titanium carbide (TiC), and tantalum carbide (TaC), etc.

A carbon material including graphite, carbon nanotube, carbon fiber, and grapheme, etc.

A boride including zirconium boride (ZrB₂), titanium boride (TiB₂), and lanthanum boride (LaB₆), etc.

A silicide including molybdenum silicide (MoSi₂), titanium silicide, and iron silicide, etc.

A nitride including titanium nitride, tantalum nitride, vanadium nitride, iron nitride, and chromium nitride, etc.

A ferroelectric oxide including barium titanate, and zirconium led titanate, etc.

A metal fine powder including iron powder, nickel powder, copper powder, and aluminum powder.

For persons skilled in the art, this principle can be applied to derive suitable microwave-absorbing materials, and a single material or a mixture of two or more of the aforementioned materials can be used in the invention.

The way of putting the microwave-absorbing material onto the particles adopts a thin film coating method, a brushing method, a spin-coating method, a screen printing method, an ink jet printing method, or even a heap spray method, and a substrate insertion method, etc.

The aforementioned thin film coating method can be a physical thin film coating (such as vacuum coating film) or a chemical thin film coating (such as chemical vapor coating film, electroplating, electroplating-free, and electrophoresis), etc.

In the aforementioned brushing method, spin-coating method, screen printing method, or ink jet printing method, the microwave-absorbing particles are spread in an appropriate solution. To facilitate the operation, an appropriate dispersant or precipitation preventing agent can be added, and it is necessary to bake dry the dispersant or precipitation preventing agent (by using microwave drying or heating drying) before the microwave irradiation takes place, so as to remove the aforementioned solutions and additives.

In the aforementioned heap spray method and substrate insertion method using a dry microwave-absorbing material (in formed of particles or lumps), the microwave-absorbing material is stacked and sprayed on the thin film and around the substrate; or the substrate together with the thin film disposed thereon is inserted into a gap of the microwave-absorbing material. The microwave-absorbing material used in this method is not limited to the form of particles, but sheets or rods can be used, too.

In the aforementioned way of putting the microwave-absorbing material, the quantity of the material should be sufficient to absorb the power provided by the microwave system, so that the amorphous silicon thin film temperature will not be less than 400° C.

Then, a microwave-absorbing material coated onto an amorphous silicon thin film of a glass, ceramic or silicon chip together with its substrate is put within a uniform microwave irradiation range inside a microwave irradiation chamber, and microwave with a frequency over 1 GHz and a power not less than 5 watts per square centimeter is used. The microwave irradiation chamber must be sealed, vacuumed or filled with a protective gas to protect the silicon thin film. The microwave frequency, the single mode or multi-mode, and the irradiation direction are optimized according to the shape of the microwave irradiation chamber. In the first preferred embodiment, a designed is provided. However, persons skilled in the art can design a feasible microwave irradiation chamber according to the properties of the microwave generator.

The microwave-absorbing material absorbs and collects microwave beams to generate heat, and the temperature can be measured by an optical pyrometer and used as a feedback control. The heating temperature used in this technique is generally controlled below 600° C. and preferably between 400° C. and 500° C., and this temperature is also affected by the quantity and position of the microwave-absorbing material, particularly the wave power. Within a specific quantity of the microwave-absorbing material and a specific irradiation by microwave power, the temperature of the microwave-absorbing material will rise to an equilibrium value, and this value varies with different microwave systems. Persons skilled in the art simply need to set these quantitative relations to obtain the equilibrium temperature without installing any temperature control device, so as to complete the microwave irradiation successfully. The irradiation time is adjusted by the microwave power and can be controlled to approximately 3000 seconds, and preferably to 1000 seconds.

Persons ordinarily skilled in the art can use this principle to derive suitable microwave frequency, mode, and irradiation direction for the shape of the microwave irradiation chamber, and these microwave frequencies, modes, and irradiation directions are intended to be covered by the scope of the present invention.

In an embodiment of the present invention, the amorphous silicon thin film (including hydrogen) with a thickness of 10 nm is coated onto a glass, ceramic or silicon chip. A layer of appropriate-quantity microwave-absorbing material is disposed on the amorphous silicon thin film or around its periphery. The microwave-absorbing material is in form of a micro-particle, a thin film, or a lump. The microwave irradiation with appropriate frequency, power and mode is used for the crystallization, particularly suitable for crystallizing a large-area amorphous silicon thin film.

The method of selecting the microwave-absorbing material has been described above. In the way of putting the microwave-absorbing material, a physical or chemical coating film method can be used for a thin film with a thickness over 50 nm, and a brushing method, a spin-coating method, a screen printing method, an ink jet printing method or even a heap spray method or a substrate insertion method can be used for particles, and the quantity of the microwave-absorbing material is controlled to over 1 milligram per square centimeter. For lumps, an appropriate number of lumps is carried by a tool, such that an appropriate gap (over 0.5 cm) exists between the amorphous thin films. The quantity (such as thickness) of the microwave-absorbing material a one of the control factors for increasing the temperature of the microwave irradiation (and another control factor is the microwave power). With the same microwave irradiation power, the more the microwave-absorbing material, the higher is the equilibrium temperature after temperature rises.

The screen printing method and the ink jet method are applicable for printing a patterned microwave-absorbing material, so that the technology of the present invention can only crystallize the part of amorphous silicon with the patterned microwave-absorbing material by microwave, but it cannot heat the microwave-absorbing material disposed around the amorphous silicon to change its properties. The third preferred embodiment provides an example of a partial crystallization method.

In the placement method used in preferred embodiments, the first embodiment adopts the brushing method, the second embodiment adopts the insertion method, and the third embodiment adopts the thin film coating method. Persons skilled in the art can implement the invention with the most suitable placement method accordingly.

The microwave irradiation uses a microwave with a frequency of 1-50 GHz depending on the accessible microwave power supply, the shape of the microwave chamber, and the applied mode. The operating power density of the microwave is controlled to over 5 watts per square centimeter. In the first preferred embodiment, an elliptic microwave chamber and its electromagnetic field simulate the distribution of the microwave field. Persons skilled in the art can implement the present invention by using the most appropriate frequency, chamber shape, mode, and uniform irradiation range (area) accordingly.

If the position and quantity of the microwave-absorbing material are controlled appropriately, the crystallization of silicon will not be less than 80% within the microwave irradiation time of 100-300 seconds, and a better electric property can be achieve within 300-600 seconds. These results will be demonstrated in the following preferred embodiments.

After the microwave irradiation is finished, it is necessary to remove the microwave-absorbing material. If the microwave-absorbing material is in the form of lumps or loosely disposed particles, the removal is basically not necessary. For the brushed microwave-absorbing material in form of particles, it is necessary to remove the material by de-ionized water, and supersonic vibrations are used, if needed. For the microwave-absorbing material in form of a thin film, an etching solution is used to etch the material, or a chemical mechanical polishing method is used to remove the material.

### First Preferred Embodiment

The main composition of the microwave accessory absorbing material includes silicon carbide and carbon substrate. The former is a general silicon carbide powder available in market, primarily of the alpha crystal type, and the later is prepared by users.

The method of preparing the carbon substrate is to prepare a water solution containing 1% of multiwall carbon nanotubes (MWCNT). Now, organic dispersant—cetyltrimethylammonium bromide (CTAB) and organic silicon—acrylic binder are required. Then, graphite powder is added into the water solution containing carbon nanotubes.

At room temperature, the graphite powder is an accessory absorbing material capable of transmitting microwave energy efficiently, and its heating temperature is relatively higher, but it has a disadvantage of having a relatively low microwave absorbing capability. The carbon nanotubes are added to compensate the low microwave absorbing capability at room temperature, so that the temperature can rise quickly at room temperature. The solution with carbon nanotubes is brushed onto the amorphous silicon thin film, and the brushed quantity is equal to 50+5 milligrams per square centimeter. The brushing method can be substituted by a screen printing method, an ink jet method or a spin-coating method. Under the microwave irradiation of 10 watts per square centimeter, the foregoing brushed quantity can increase the temperature up to a range of 400-500° C. after 40 seconds and to an equilibrium temperature of 500° C. after 50 seconds.

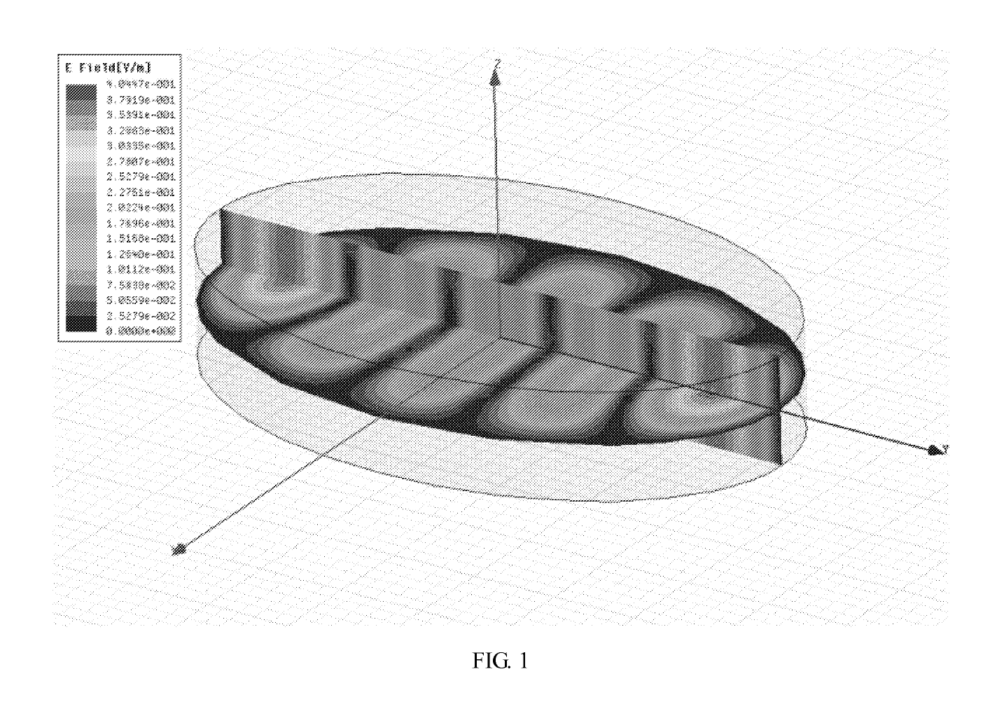

The prepared amorphous silicon thin film together with the substrate is put into a preheated chamber. The chamber is designed with the outermost layer made of a refractory asbestos material and the middle layer with an installed magnesium oxide thin plate to prevent a direct contact of a sample with the chamber. The internal space of this microwave system is substantially elliptic. The distribution of microwave fields of this system simulated by electromagnetic fields is shown in FIG. 1. The microwave fields in the system are in a basic stable mode. The basic mode corresponds to a microwave frequency of 2.37 GHz, and a module of TE₁₀₃. The strongest microwave field occurs at the conjugate point along the long axis, and the area of the block is approximately equal to 3.4×3.4 square centimeters. The sample is put into this area to obtain the stable optimal conditions of the microwave field. Persons skilled in the art can base on the shape of the microwave irradiation chamber and the simulation of the electromagnetic field to obtain a large area of uniform microwave irradiation field, which is suitable for the use in the microwave irradiation of a large-area amorphous silicon thin film.

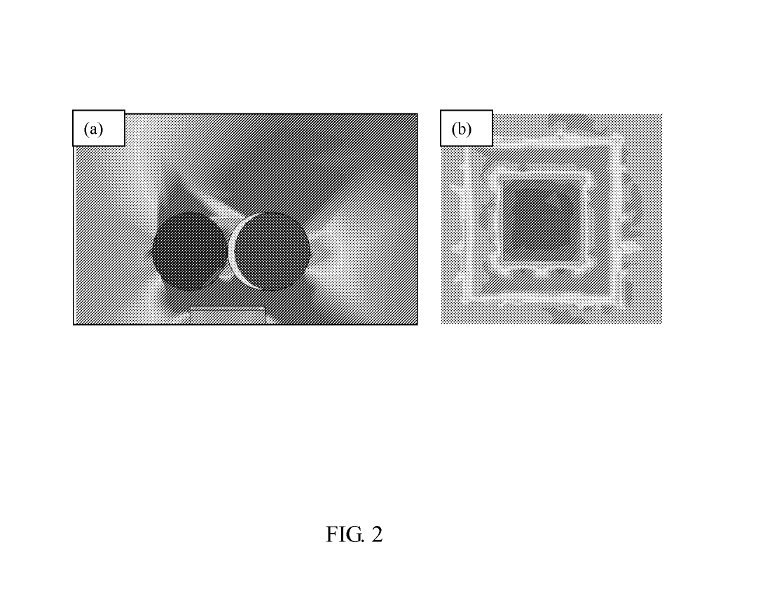

The design and disposition of the microwave accessory absorbing material are used to concentrate the microwave fields at a surface of the microwave accessory absorbing material and generate a uniform thermal field to achieve the thermal effect of the microwave, or the heated amorphous silicon thin film is used to absorb microwave energy quickly. The dielectric loss in the microwave field of the heated amorphous silicon can be absorbed to a certain extent, and heat can be generated automatically, and the silicon atoms can be rearranged into the crystalline mode more quickly. Since the microwave heating is a self heating, unlike the conventional external heating through heat conduction or radiation. With reference to FIG. 2 for a simulation of an electromagnetic field distributed in a microwave field of a sample and a simulation of an electromagnetic field distributed in a microwave field around a microwave-absorbing material, FIG. 2(a) shows that the distribution of the microwave fields is affected by the silicon carbide rods coated with the microwave-absorbing material, and the microwave fields are concentrated at a surface of the microwave accessory absorbing material to produce a uniform microwave field. FIG. 2(b) shows that a change of microwave fields in a sample and silicon carbide particles coated with a single layer of the microwave-absorbing material. The intensity of the microwave field obviously changes from the outer side towards the interior of the sample, indicating that the microwave energy is absorbed by the sample and the microwave accessory absorbing material.

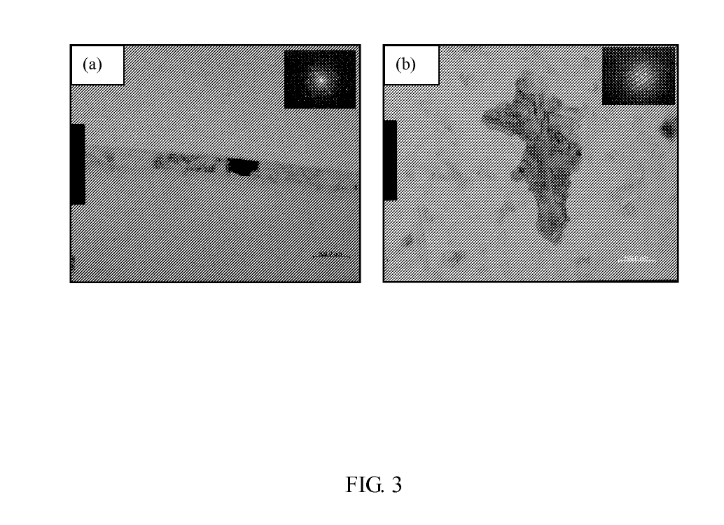

Three main effects of carbon include concentrating the intensity of the concentrated microwave field, converting the absorbed microwave energy into heat energy, and assisting the absorption of extra microwave energy. A piece of asbestosis covered onto the chamber to prevent heat from being dispersed quickly. The microwave irradiation uses the microwave with a frequency of 2.37 GHz to heat the sample. The microwave field is outputted for 60 seconds to preheat and adjust the reflected microwave power. After the preheated is finished, the microwave power is adjusted to an appropriate value of the power and outputted. The outputted microwave power is fine tuned to maintain the temperature of the chamber to prevent the glass substrate from being softened. The microwave operating power density is controlled to 5-300 watts per square centimeter, which falls within a general commercial microwave product. The thermal treatment time is controlled to approximately 100 seconds to achieve the crystallization, but the time can be extended to 1000 seconds for better electric properties. After the thermal treatment by microwave, a polysilicon thin film as shown in FIG. 3(a) is obtained. The thickness of the silicon thin film is approximately equal to 40 nm, and the polysilicon thin film containing approximately 200 nano-crystalline particles microwave as shown in FIG. 3(b) is obtained after the thermal treatment is finished. After the thermal treatment by microwave is finished, the crystalline particles are in the shape of an island, and the crystalline structure is close to a single-crystal structure as shown in the electric diffraction in FIG. 3(b). The diameters of crystalline particles obtained by different crystallization methods are compared (refer to Table 1), and the crystalline particle greater than 200 nm can be obtained after the thermal treatment by microwave. Compared with the common commercial excimer-laser annealing (ELA) method, the crystalline particle can be twice bigger, so that the number and affection of the grain boundary can be reduced, and the effect of having excessive current leakage can be avoided.

TABLE 1
Comparison of sizes of crystal particles of an amorphous silicon thin film
obtained by different crystallization methods

| | Solid-phase | | Excimer- | Microwave |
|---|---|---|---|---|
| | Crystal- | Metal-induced | laser | Irradiation |
| Crystallization | lization | Crystallization | Annealing | of the |
| Method | (SPC) | (MIC) | (ELA) | Invention |
| Crystal Particle | >0.3 μm | <0.3 μm | ~0.1 μm | >0.2 μm |
| Size | | | | |

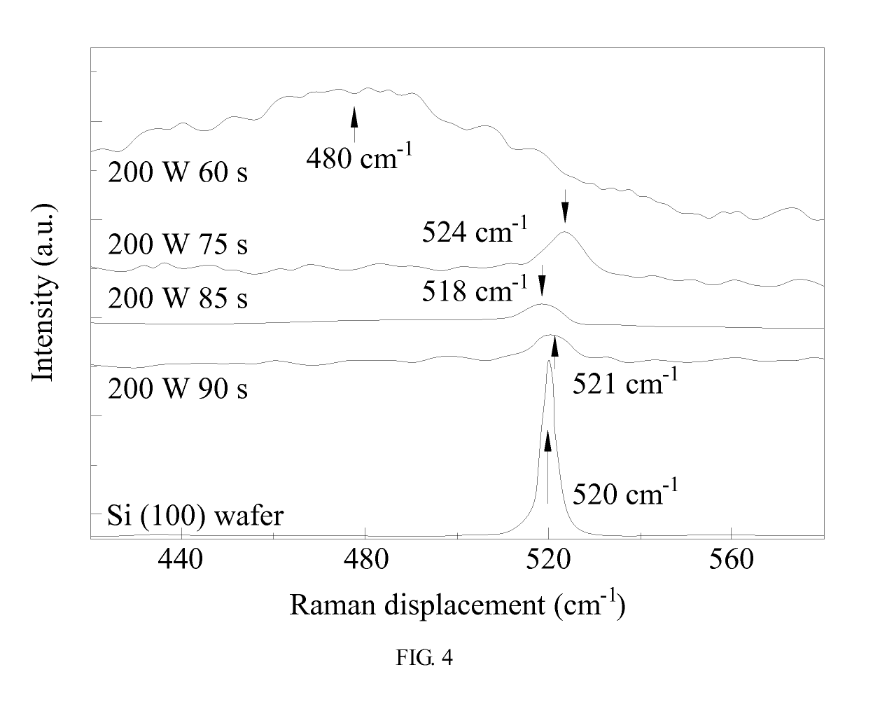

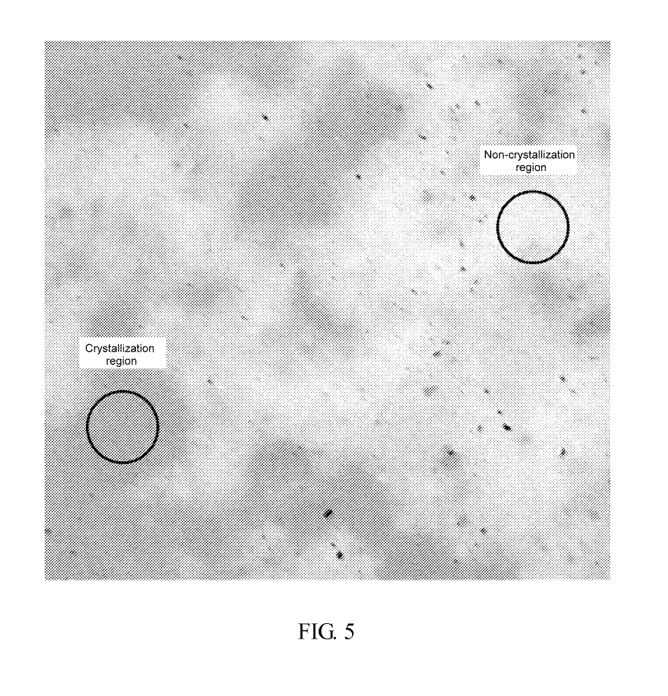

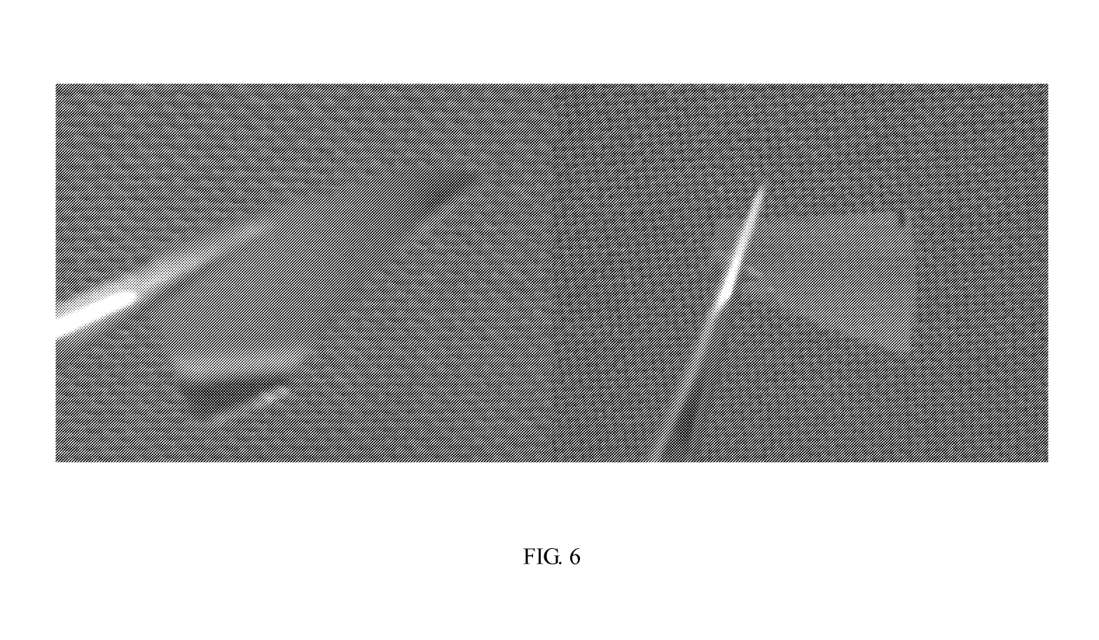

After the sample has gone through the thermal treatment by microwave, measurements show that the Raman peak shifts gradually from an amorphous position of 480 cm⁻¹ to a crystallization position of 521 cm⁻¹. In FIG. 4, the peak width is changed from a wider waveform to a sharper waveform. The amorphous silicon thin film is processed by microwave irradiation with a microwave power density over 10 watts per square centimeter, so that the position of the Raman peak is almost superimposed with the peak of the single-crystal silicon. It shows that the crystallinity of the sample is closed to the level of fully crystallized, and the crystallinity of the thin film can reach at least to a level of 80%. FIG. 5 shows a photo of a thin film crystallization region (in grayish black color) and an amorphous region (in grayish white color) taken by an optical microscope, and both regions can be distinguished easily. Based on X-ray diffraction charts, the silicon thin film crystallized by microwave and the fully crystallized polysilicon thin film are compared, and the silicon thin film coated with the microwave-absorbing material and processed by the microwave irradiation can easily have a crystallization area of over 95%. FIG. 6 shows the colors of the thin films before and after being crystallized by 95%, wherein the amorphous thin film shows a purplish red color, and the crystallized thin film shows a light yellowish orange color. The amorphous silicon thin film irradiated by microwave with a microwave power density of 20-100 watts per square centimeter can shorten the crystallization time drastically by more than 80% or several times. However, overheat occurs easily, and the quantity (or thickness, or weight per unit area) of the microwave-absorbing material can be reduced and controlled.

The effect of the present invention becomes apparent with the detailed description of this preferred embodiment. Compared with the conventional heating furnace used together with the microwave irradiation, if the temperature is 500° C., the required crystallization time is approximately 9 hours and 20 minutes, but if the temperature is 550° C., the required crystallization time is only 46 minutes. The present invention can complete the crystallization in 100 seconds, and thus the crystallization time is 336 times and 28 times faster to save energy and manufacturing time substantially. The present invention can be performed at room temperature, in addition to the advantages on the microwave-absorbing material and the thin film.

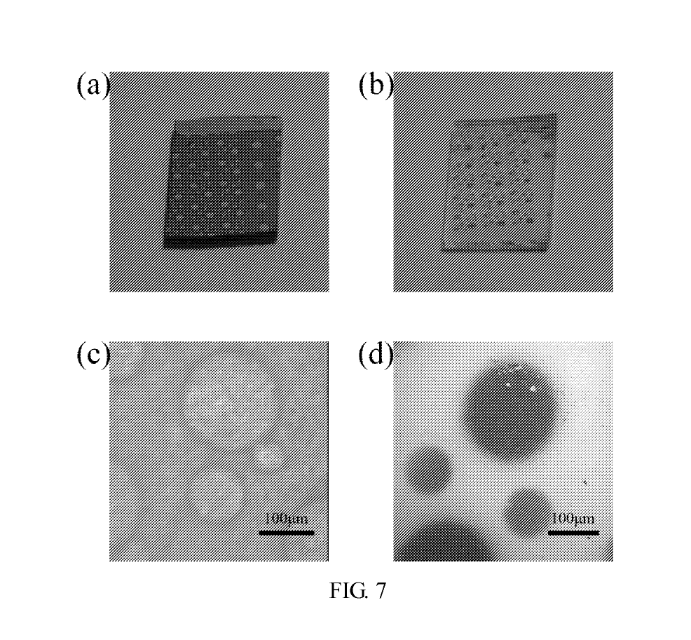

FIG. 7 shows photos comparing silicon templates before/after the microwave crystallization process taking place; 7(a) is a photo showing an amorphous silicon thin film before being irradiated by microwave; 7(b) is a photo showing an a crystalline silicon thin film after being irradiated by microwave and crystallized; 7(c) is an optical microscopic photo showing a pattern of an amorphous silicon before being irradiated by microwave; and 7(d) is an optical microscopic photo showing a pattern of an amorphous silicon before being irradiated by microwave and crystallized.

### Second Preferred Embodiment

Sputtering, low-pressure chemical vapor coating film, plasma assisted chemical vapor coating film are used for growing the amorphous silicon thin film, so that the thin film contains hydrogen and can have a thickness of 40-300 nm. Phosphorous-doped N-type and boron-doped P-type amorphous silicon thin film can be used. The microwave-absorbing material can be silicon carbide which is put onto an amorphous silicon thin film together with its substrate and around the amorphous silicon thin film, or placed in microwave reactor with a concentrated electric field of 2.45+0.20 GHz. In a protective atmosphere or atmosphere, a microwave irradiation with a power density of 25 watts per square centimeter is used for the process. The crystallization temperature range can be controlled within a range of 400-500⁹C by controlling the thickness or quantity of the microwave-absorbing material, and the irradiation time of 100 seconds, but an irradiation time of 300 seconds or 600 seconds can achieve a polysilicon thin film with better electric properties. Table 2 provides test results to compare the performance of mainstream products of a conventional low temperature polysilicon thin film transistor (LTPS-TFT) and an amorphous silicon thin film transistor (a-Si TFT) silicon thin film.

From Table 2, the carrier concentration of the microwave irradiation silicon thin film irradiated by 300 seconds is better than that by 600 seconds, and the P-type carriers have a concentration up to 3.88×10¹⁹ per cc, and the N-type carriers have a concentration up to 1.38×10²⁰ per cc. The best electron mobility can be achieved by a microwave irradiation for 600 seconds, and the P-type carriers can have electron mobility up to 12.2 cm²/Vs, and the N-type carriers can have electron mobility up to 177 cm²/Vs. These properties plus the resistivity can compete with or surpass the products crystallized by the ELA method. The required crystallization time does not exceed 600 seconds.

From the foregoing preferred embodiment, we know that the crystalline silicon thin film obtained by the present invention can lower the manufacturing temperature to provide a polysilicon thin film. Unlike the prior art, other parts of the microwave irradiation system other than the thin film and the microwave-absorbing material can be maintained at room temperature or a low temperature. The microwave assisted crystallization can increase the temperature for the manufacturing process quickly, so that the present invention can shorten the operating time, and the whole process from material feed to material output is controlled to a level of 1000 seconds, and thus saving production cost significantly and broadening the scope of applicability in the crystalline semiconductor industry. The present invention substantially breaks through the development of the low-temperature crystalline silicon.

TABLE 2
Comparison between a silicon thin film crystallized by microwave and a
traditional product

| Microwave | | Carrier | Carrier | |
|---|---|---|---|---|
| Irradiation | Conductive | Concentration | Mobility | Resistivity- |
| Time (sec) | type | (cm⁻³) | (cm²/Vs) | cm |
| 300 seconds | P-type | 3.88 × 1019 | 12.2 | 0.0132 |
| 600 seconds | P-type | 1.12 × 1019 | 177 | 0.00315 |
| 300 seconds | N-type | 1.38 × 1020 | 3.41 | 0.0133 |
| 600 seconds | N-type | 7.44 × 1019 | 17.9 | 0.00468 |
| LTPS-TFT | | | >100 | 0.001-0.01 |
| a-Si TFT | | | 0.5-1 | >100 |

### Third Preferred Embodiment

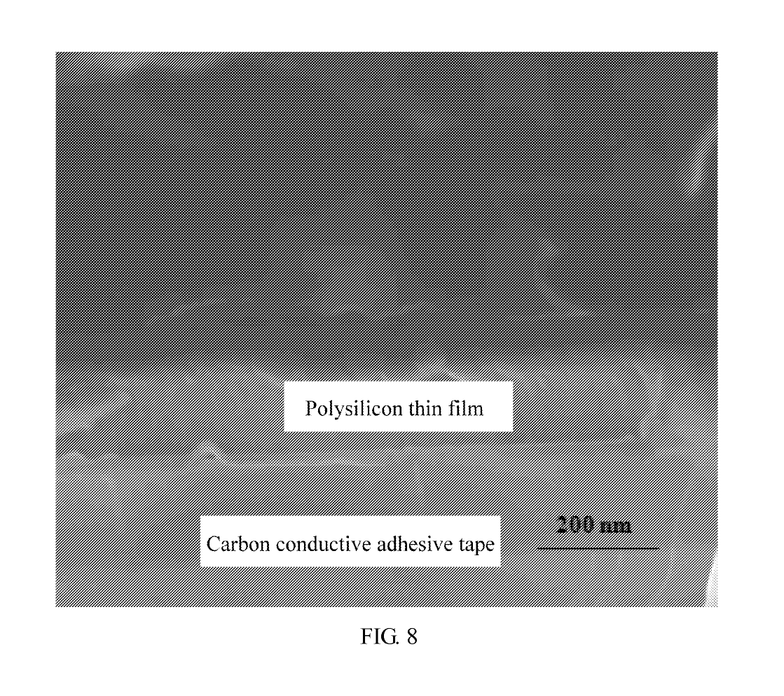

A sputtering coating film system is used for manufacturing a three-layer sandwich structured (C/a-Si/C) thin film sample, wherein C stands for a carbon thin film microwave-absorbing material made by a vacuum sputtering method and having a thickness of 50 nm; a-Si stands for amorphous silicon made by the vacuum sputtering method and having a thickness of 150 nm. To control the temperature, silicon carbide lumps are put around the sample, and then the sample is put into a microwave reactor with a high-frequency electric field of 2.45+0.20 GHz and irradiated by microwave with a microwave power of 10 watts per square centimeter at atmosphere for 600 seconds to manufacture a polysilicon thin film. In the crystallization process, if the silicon is crystallized at the same time, the carbon thin film will be reacted and consumed by air. Therefore, when the crystallization of the polysilicon thin film is finished, the carbon thin film will be reached and exhausted as well. The final product of the sample becomes a carbon-free polysilicon thin film. Besides the thin film structure, a hard photomask can be used to further reduce the thin film with a structure of smaller devices. FIG. 8 shows the comparison of a sample before and after the crystallization by microwave takes place. FIGS. 8(a)-8(d) clearly distinguishes the change before and after the crystallization by microwave takes place.

The crystallized polysilicon sample can be attached by using an adhesive tape or removed or transferred to any substrate (including a plastic substrate). FIG. 9 shows a crystalline silicon sample transferred from a glass substrate onto a carbon conductive adhesive tape, and we can clearly observe the integrity of the transferred polysilicon sample. This shows two facts. 1. The micro-domain microwave crystallization is feasible. 2. The method of the present invention can be used for transferring a microwave crystallized sample to any substrate. In other words, the polysilicon sample can be applied to various different products. Further, the multi-layer film structure can be applied for manufacturing 3D-IC workpieces.

The present invention skillfully uses a small quantity of the microwave-absorbing material to attract and collect microwave beams on the amorphous silicon thin film, and the thermal effect of the microwave beams to heat the microwave-absorbing material, so that the amorphous silicon thin film reaches the critical temperature. With this temperature or above, the collected microwave beams will induce vibrations of a cluster of atoms in the amorphous silicon and result in a low temperature, which is called a non-thermal effect of the microwave. The thermal effect and the non-thermal effect of the microwave are combined to achieve the outstanding effect of reducing the crystallization time below 1000 seconds at a relatively low temperature (such as 500° C.).

What is claimed is:

1. A method of crystallizing an amorphous silicon thin films by microwave irradiation, combining a microwave-absorbing material with an amorphous silicon thin film, and using microwave irradiation to crystallize the amorphous silicon thin film, and the method comprising the following two steps of:
putting the microwave-absorbing material on top or around of the amorphous silicon thin film to form a composite; and
moving the composite into a microwave irradiation chamber, and irradiating the composite by microwave with appropriate frequency and power to crystallize the amorphous silicon thin film.

2. The method of crystallizing an amorphous silicon thin film by microwave irradiation as recited in claim 1, wherein the microwave-absorbing material is one selected from the collection of semiconductive metal oxide, magnetic oxide, carbonaceous material, carbide, nitride, silicide, boride, ferroelectric oxide, metal powder, or a combination of the above.

3. The method of crystallizing an amorphous silicon thin film by microwave irradiation as recited in claim 1, wherein the microwave-absorbing material is in a form of thin film, micro-particle or lump.

4. The method of crystallizing an amorphous silicon thin film by microwave irradiation as recited in claim 1, wherein the microwave-absorbing material is put on top or around of the amorphous silicon thin film by a method selected from the collection of thin film plating method, brushing method, spin-coating method, screen printing method, ink jet printing method, heap spray method, substrate insertion method or a combination of the above.

5. The method of crystallizing an amorphous silicon thin film by microwave irradiation as recited in claim 1, wherein the appropriate frequency falls within a range of 1-50 GHz; and the power has a density over 5 watts per square centimeter.

6. The method of crystallizing an amorphous silicon thin film by microwave irradiation as recited in claim 1, wherein a specific pattern is formed at a part of the microwave-absorbing material, and when the microwave irradiation is performed, the amorphous silicon thin film is partially crystallized to form a crystalline silicon film corresponding to the specific pattern.

7. The method of crystallizing an amorphous silicon thin film by microwave irradiation as recited in claim 1, wherein the microwave irradiation chamber is provided for irradiating microwave onto a multi-layer film containing the amorphous silicon of the amorphous silicon thin film, so that the multi-layer film can be removed and transferred to a substrate after the multi-layer film is crystallized.
